(19) United States
(12) Patent Application Publication
(10) Pub. No.: US 2015/0014772 A1
(43) Pub. Date: Jan. 15, 2015

(54) PATTERNING FINS AND PLANAR AREAS IN SILICON

(71) Applicant: International Business Machines Corporation, Armonk, NY (US)

(72) Inventors: Kangguo Cheng, Schenectady, NY (US); Shom Ponoth, Gaithersburg, MD (US); Balasubramanian Pranatharthiharan, Watervliet, NY (US); Theodorus E. Standaert, Clifton Park, NY (US); Tenko Yamashita, Schenectady, NY (US)

(21) Appl. No.: 13/939,665

(22) Filed: Jul. 11, 2013

(51) Int. Cl. H01L 21/308; H01L 27/06

(52) U.S. Cl. CPC H01L 21/3086; H01L 27/0617
USPC 257/347; 438/703; 257/368

(57) ABSTRACT

A method including for forming a plurality of mandrels, a plurality of sidewall spacers, and a plurality of offset spacers above a hardmask layer, the sidewall spacers being separated by the plurality of mandrels and the plurality of offset spacers in an alternating order, each of the plurality of sidewall spacers being in direct contact with a single offset spacer and a single mandrel, the plurality of mandrels being separated from the plurality of offset spacers by the plurality of sidewall spacers, depositing a fill material above the plurality of mandrels, above the plurality of sidewall spacers, above the plurality of offset spacers, and above the hardmask layer, and removing the plurality of mandrels and the plurality of offset spacers selective to the plurality of sidewall spacers, the fill material, and the hardmask layer.

### BACKGROUND

1. Field of the Invention

The present invention generally relates to semiconductor device manufacturing, and more particularly to simultaneously patterning a finFET device region and a planer device region with similar heights.

2. Background of Invention

Semiconductor device manufacturing generally includes various steps including a patterning process. For example, the manufacturing of a semiconductor chip may start with, for example, CAD (computer aided design) generated device patterns and may continue with the effort to replicate these device patterns in a substrate in which semiconductor devices can be formed. The replication process may involve the use of a photolithography process in which a layer of photo-resist material may be first applied on top of a substrate, and then be selectively exposed according to a pre-determined device pattern. Portions of the photo-resist that are exposed to light or other ionizing radiation (e.g., ultraviolet, electron beams, X-rays, etc.) may experience some changes in their solubility to a certain solution. Next, the photo-resist may be developed in a developer solution, thereby removing the non-irradiated (in a negative resist) or irradiated (in a positive resist) portions of the resist layer, to create a photo-resist pattern. The photo-resist pattern may subsequently be copied or transferred to the substrate underneath the photo-resist pattern.

Engineers are continuously facing the challenge of how to meet the market demand for ever increasing device density. One technique for tight pitch patterning is to achieve twice the pattern density through a technique called sidewall image transfer (SIT), also known as sidewall spacer image transfer. A typical SIT process can include lithographically forming a mandrel above a substrate from a suitable photo-resist material. A material suitable for forming spacers is subsequently deposited on top of the mandrel and to eventually form spacers next to the mandrels. The mandrel can then be removed and the remaining spacers can define the desired device pattern. The SIT technique may be used to produce the fins for multiple fin field effect transistors (hereinafter “finFET”) within a finFET device region. Typically, regions of a wafer not designated as the finFET device region may be recessed below a top surface of the fins. The regions of the wafer not designated as the finFET device region may be designated as a planar device region. One or more masking steps may be required in addition to the typical SIT technique to achieve both a finFET device region and a planar device region with substantially similar heights.

### SUMMARY

According to one exemplary embodiment of the present invention, a method is provided. The method may include forming a plurality of mandrels, a plurality of sidewall spacers, and a plurality of offset spacers above a hardmask layer, the sidewall spacers being separated by the plurality of mandrels and the plurality of offset spacers in an alternating order, each of the plurality of sidewall spacers being in direct contact with a single offset spacer and a single mandrel, the plurality of mandrels being separated from the plurality of offset spacers by the plurality of sidewall spacers, depositing a fill material above the plurality of mandrels, above the plurality of sidewall spacers, above the plurality of offset spacers, and above the hardmask layer, and removing the plurality of mandrels and the plurality of offset spacers selective to the plurality of sidewall spacers, the fill material, and the hardmask layer.

According to another exemplary embodiment of the present invention, a method is provided. The method may include forming a set of sidewall spacers above a hardmask layer along opposite sidewalls of a mandrel, the hardmask layer being on top of a substrate, depositing an offset material above the mandrel and above the set of sidewall spacers, the offset material substantially filling a space between adjacent sidewall spacers, and removing a portion of the offset material to expose a top surface of the mandrel, a remaining portion of the offset material forming an offset spacer along a sidewall of the set of sidewall spacers. The method may further include depositing a fill material above the mandrel, above the set of sidewall spacers, and above the offset spacer, removing the mandrel and the offset spacer selective to the set of sidewall spacers, the fill material, and the hardmask layer, transferring a fin pattern defined by the set of sidewall spacers and the fill material oxide into the substrate, and removing the set of sidewall spacers.

According to another exemplary embodiment of the present invention, a method is provided. The method may include a finFET device region comprising a plurality of fins made from a semiconductor material, and a planar device region made from a similar semiconductor material as the finFET device region, a top surface of the plurality of fins in the finFET device region being substantially flush with a top surface of the planar device region.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1 is a top view of a structure at an intermediate step of fabrication in which the formation of a mandrel is illustrated according to an exemplary embodiment.

FIG. 1A is a cross section view of FIG. 1, taken along section line A-A.

FIG. 2 is a top view of the structure at an intermediate step of fabrication in which a dielectric layer may be conformally deposited above the structure according to an exemplary embodiment.

FIG. 2A is a cross section view of FIG. 2, taken along section line A-A.

FIG. 3 is a top view of the structure at an intermediate step of fabrication in which the formation of sidewall spacers is illustrated according to an exemplary embodiment.

FIG. 3A is a cross section view of FIG. 3, taken along section line A-A.

FIG. 4 is a top view of the structure at an intermediate step of fabrication in which an offset material may be conformally deposited above the structure according to an exemplary embodiment.

FIG. 4A is a cross section view of FIG. 4, taken along section line A-A.

FIG. 5 is a top view of the structure at an intermediate step of fabrication in which the formation of offset spacers is illustrated according to an exemplary embodiment.

FIG. 5A is a cross section view of FIG. 5, taken along section line A-A.

FIG. 6 is a top view of the structure at an intermediate step of fabrication in which a fill material may be deposited above the structure according to an exemplary embodiment.

FIG. 6A is a cross section view of FIG. 6, taken along section line A-A.

FIG. 7 is a top view of the structure at an intermediate step of fabrication in which the mandrel and the offset spacer are removed according to an exemplary embodiment.

FIG. 7A is a cross section view of FIG. 7, taken along section line A-A.

FIG. 8 is a top view of the structure at an intermediate step of fabrication in which a fin pattern may be transferred into an underlying substrate according to an exemplary embodiment.

FIG. 8A is a cross section view of FIG. 8, taken along section line A-A.

FIG. 9 is a top view of the final structure according to an exemplary embodiment.

FIG. 9A is a cross section view of FIG. 9, taken along section line A-A.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Current sidewall image transfer (SIT) techniques described above may have drawbacks including, for example, requiring one or more additional steps to integrate planar device fabrication into a typical SIT finFET process flow. The embodiments of the present invention generally relate to integrating planar device fabrication into a finFET process flow using a SIT technique without requiring any additional masking steps. More specifically, automatically fabricating a planar slab of silicon during fin patterning using a sidewall image transfer technique.

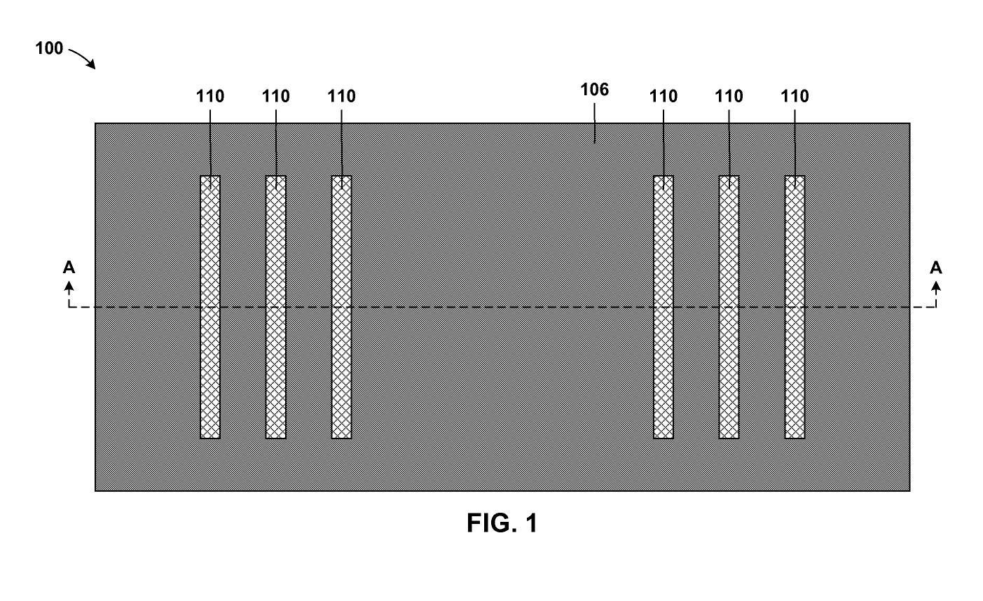

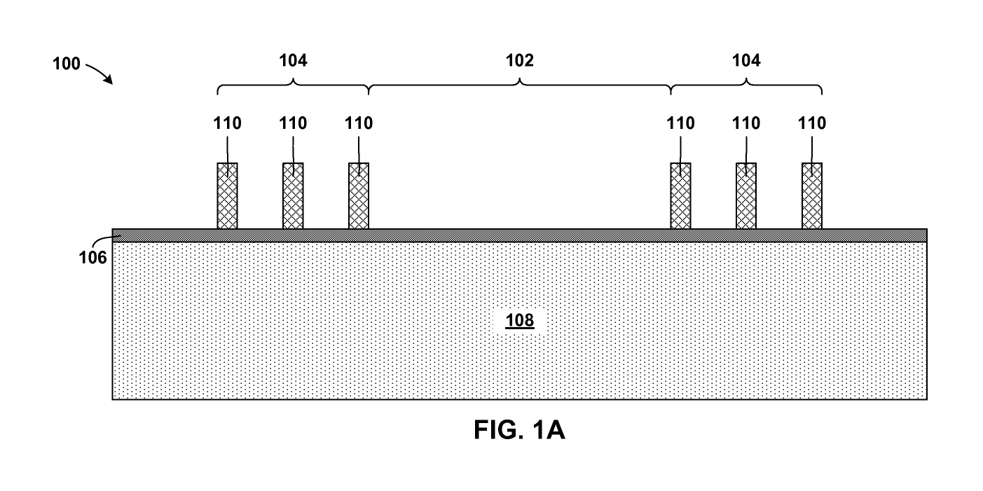

Ideally, it may be preferable to fabricate a planar device region and a finFET device region having substantially similar heights without the need for additional masking steps. One way to do so may include depositing one or more fill materials which may be used to prevent the recess of the planar device areas. One embodiment by which to fabricate the planar device region concurrently in a SIT finFET process flow without additional masking steps is described in detail below by referring to the accompanying drawings FIGS. 1-9. In the present embodiment, a fill material may be used to effectively prevent the recess of the planar device region during a typical SIT finFET process flow.

FIGS. 1 and 1A are a demonstrative illustration of a structure 100 during an intermediate step of a method of concurrently forming a planar device area and a finFET device area using a SIT finFET process flow according to one embodiment. More specifically, the method may begin with providing a hardmask layer 106 above a substrate 108, and subsequently forming a mandrel 110 on top of the hardmask layer 106. FIG. 1 illustrates the structure 100 from a top view. FIG. 1A is a cross section view of FIG. 1 taken along section line A-A. The substrate 108 may include a bulk semiconductor or a layered semiconductor such as Si/SiGe, a silicon-on-insulator (SOI), or a SiGe-on-insulator (SGOI). Bulk substrate materials may include undoped Si, n-doped Si, p-doped Si, single crystal Si, polycrystalline Si, amorphous Si, Ge, SiGe, SiC, SiGeC, Ga, GaAs, InAs, InP and all other III/V or II/VI compound semiconductors. A bulk substrate is illustrated in the figures and is relied upon for the corresponding discussion. The hardmask layer 106 may include multiple layers. In one embodiment, the hardmask layer 106 may include silicon oxide, silicon nitride, a metal-nitride, such as titanium-nitride (TiN), boron-nitride (BN), or a metal-oxide, or any combination thereof. Further, in one embodiment, the hardmask layer 106 can have a thickness, in some embodiments, ranging from about 5 nm to about 80 nm.

The mandrel 110 can be generated using known photolithography and masking techniques. During this step, a mandrel layer can be formed on top of the hardmask layer 106. The mandrel layer can include amorphous silicon or any silicon based compound, for example, silicon nitride, silicon oxide, or silicon carbon, or alternatively amorphous carbon. The mandrel layer may preferably include a material that is different enough from the material of the sidewall spacers (described below) and the material of the hardmask layer 106 so that it can be selectively removed. The particular material chosen can partly depend upon the desired pattern to be formed and the materials chosen in subsequent steps discussed below. In one embodiment, the mandrel layer can be formed with a vertical thickness ranging from about 30 nm to about 150 nm. The mandrel layer can then be lithographically patterned to create the mandrel 110. The mandrel 110 can be formed by applying known patterning techniques involving exposing a photo-resist and transferring the exposed pattern of the photo-resist by etching the mandrel layer. The mandrel 110 may be formed in a finFET device region 104 of the structure 100. The finFET device region 104 can be distinguished from the remainder of the structure 100, in that finFET devices may be formed in the finFET device region 104. Areas of the structure adjacent to the finFET device region 104 may subsequently be used to for planar semiconductor devices, and as such may be referred to as the planar device region 102.

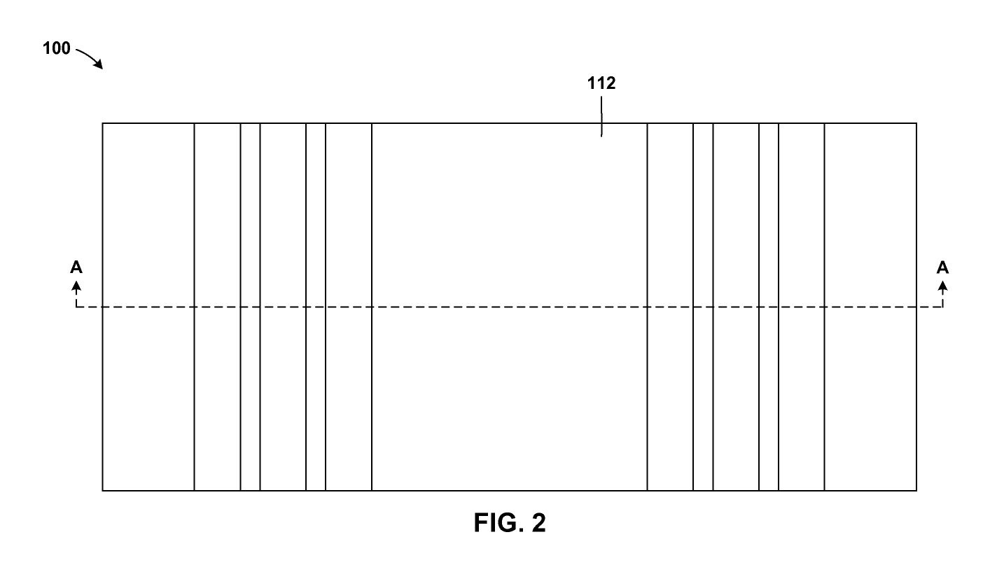

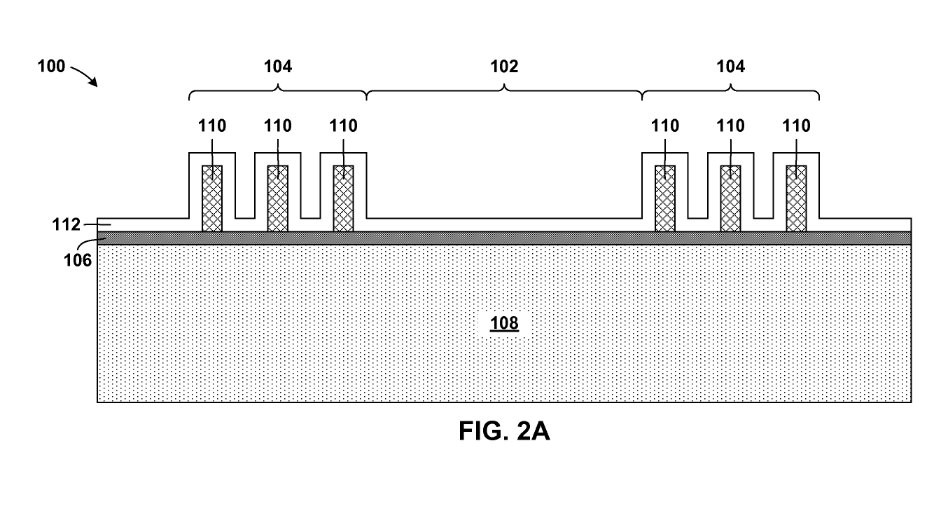

FIGS. 2 and 2A are a demonstrative illustration of the structure 100 during an intermediate step of a method of concurrently forming the planar device region and the finFET device region using a SIT finFET process flow according to one embodiment. More specifically, the method can include conformally depositing a layer of dielectric material 112 (hereinafter “dielectric layer”) directly on top of the hardmask layer 106 and the mandrel 110. FIG. 2 illustrates the structure 100 from a top view. FIG. 2A is a cross section view of FIG. 2 taken along section line A-A. In one embodiment, the dielectric layer 112 can include, for example, silicon nitride or silicon oxide. It should be noted, however, that the dielectric layer 112 should be of a material capable of being removed selective to the hardmask layer 106. For example, if the hardmask layer 106 is an oxide then the dielectric layer 112 may preferably be a nitride, or alternatively, if the hardmask layer 106 is a nitride then the dielectric layer 112 may preferably be an oxide. The dielectric layer 112 can be deposited with a conformal deposition technique, using any known atomic layer deposition technique, molecular layer deposition techniques, or future developed deposition technique. In one embodiment, the dielectric layer 112 can have a substantially uniform thickness. In one embodiment, the dielectric layer 112 can have a conformal and uniform thickness ranging from about 5 nm to about 50 nm.

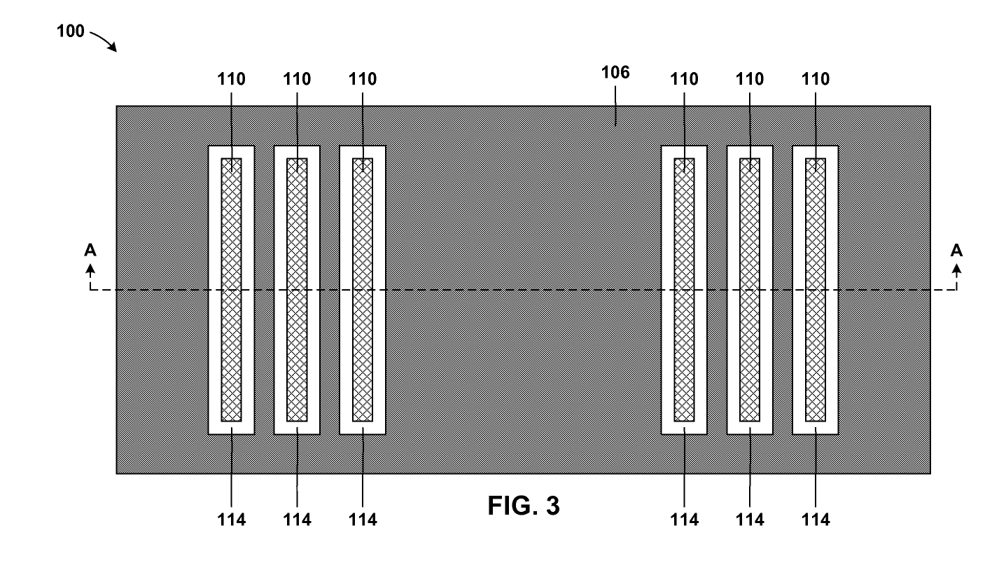

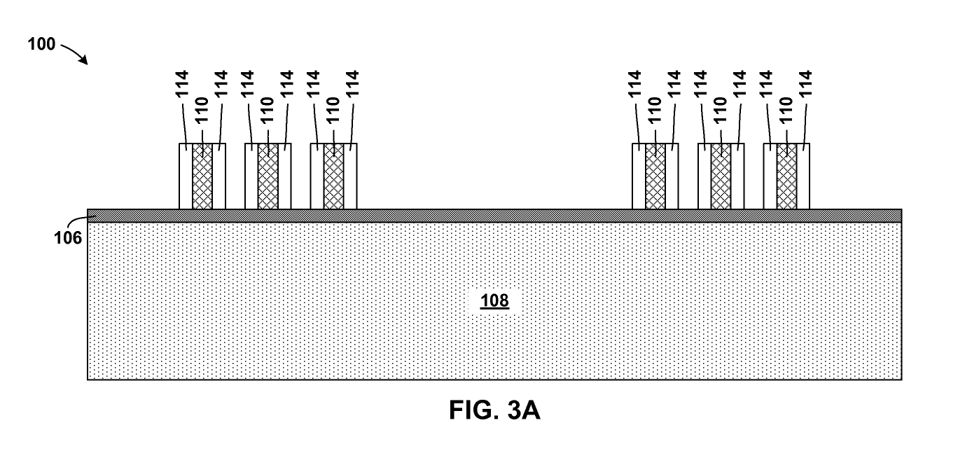

FIGS. 3 and 3A are a demonstrative illustration of the structure 100 during an intermediate step of a method of concurrently forming the planar device region and the finFET device region using a SIT finFET process flow according to one embodiment. More specifically, the method can include forming sidewall spacers 114 by subjecting the dielectric layer 112 (FIG. 2) to a directional etching process such as a reactive-ion-etching technique. FIG. 3 illustrates the structure 100 from a top view. FIG. 3A is a cross section view of FIG. 3 taken along section line A-A. The directional etching process can remove a portion of the dielectric layer 112 (FIG. 2) from above the hardmask layer 106 and from the top of the mandrel 110. A portion of the dielectric layer can remain along opposite sidewalls of the mandrel 110, forming the sidewall spacers 114. Furthermore, the mandrel 110 and the sidewall spacers 114 should each include materials that would allow the mandrel 110 to be subsequently removed selective to the sidewall spacers 114. Here, it should also be noted that the sidewall spacers 114 depicted in FIGS. 3 and 3A are for illustration purposes and generally can have a slightly different shape from those shown. For example, the sidewall spacers 114 can have rounded corners that can be naturally formed during the directional etching process as is known in the art. The sidewall spacers 114 will eventually define a fin pattern which ultimately can be transferred into the underlying substrate 108.

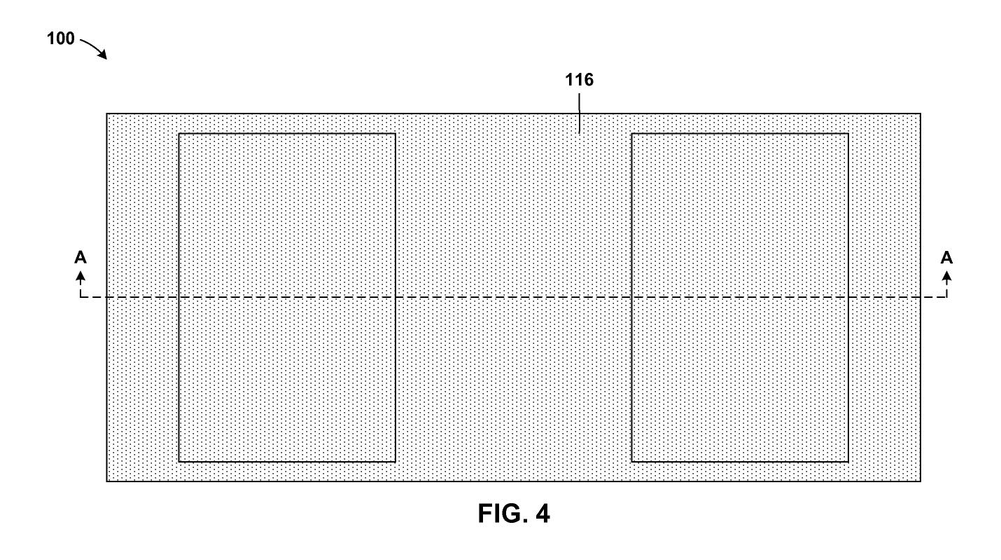

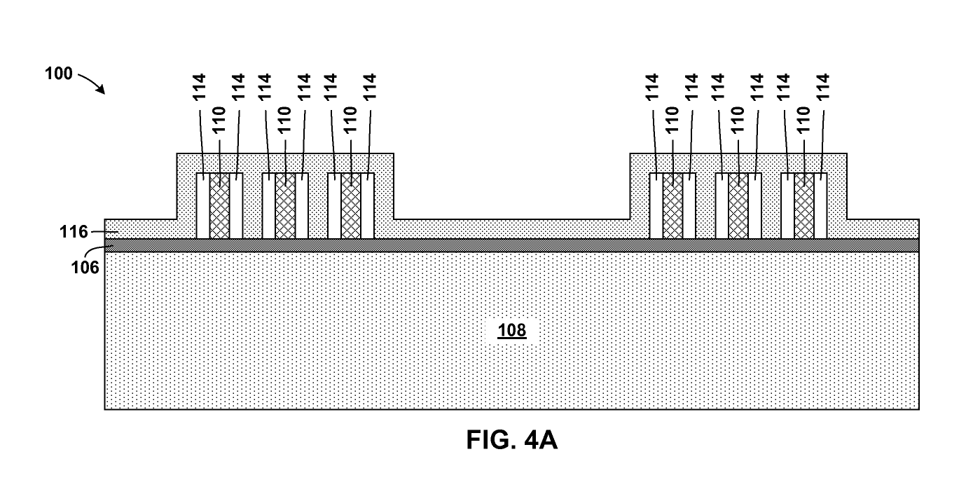

FIGS. 4 and 4A are a demonstrative illustration of the structure 100 during an intermediate step of a method of concurrently forming the planar device region and the finFET device region using a SIT finFET process flow according to one embodiment. More specifically, the method can include conformally depositing an offset material 116 above the structure 100. FIG. 4 illustrates the structure 100 from a top view. FIG. 4A is a cross section view of FIG. 4 taken along section line A-A. In one embodiment, the offset material 116 can include, for example, amorphous silicon. The offset material 116 can be deposited with a conformal deposition technique, using any known atomic layer deposition technique, molecular layer deposition techniques, or future developed deposition technique. The offset material 116 can have a substantially uniform thickness. In one embodiment, the offset material 116 may be deposited with a thickness equal to the space between adjacent sidewall spacers 114. Therefore, the target thickness of the offset material 116 may depend on the spacing between two adjacent sidewall spacers 114.

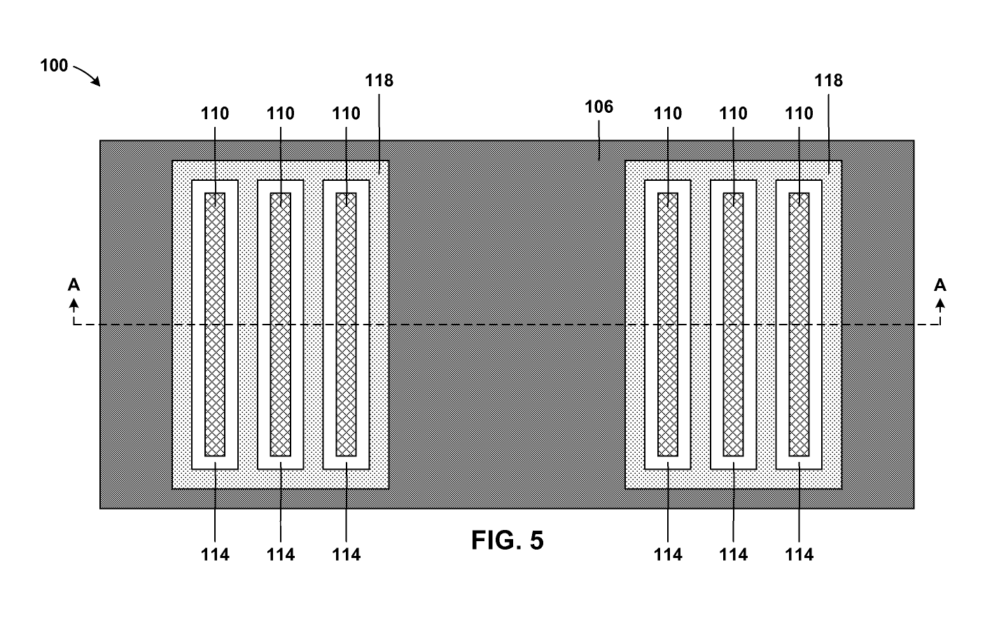

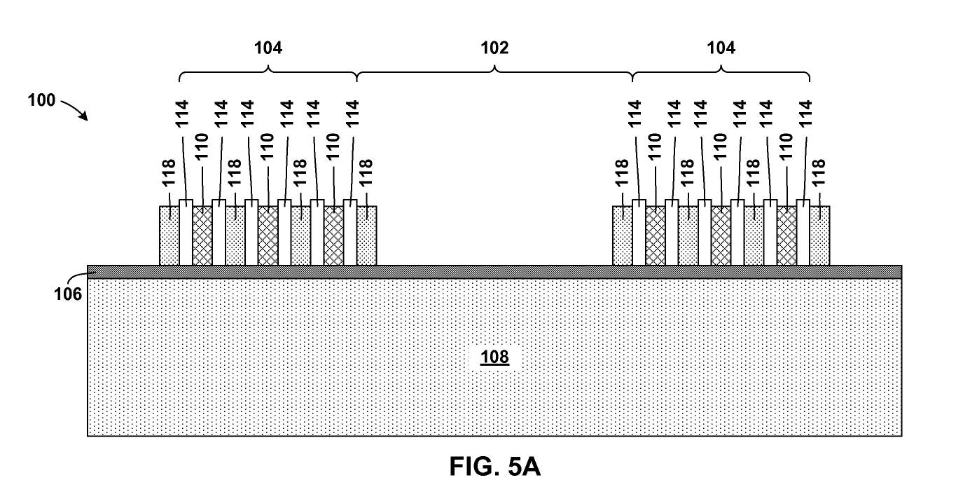

FIGS. 5 and 5A are a demonstrative illustration of the structure 100 during an intermediate step of a method of concurrently forming the planar device region and the finFET device region using a SIT finFET process flow according to one embodiment. More specifically, the method can include forming offset spacers 118 by subjecting the offset material 116 (FIG. 4) to a directional etching process such as a reactive-ion-etching technique. FIG. 5 illustrates the structure 100 from a top view. FIG. 5A is a cross section view of FIG. 5 taken along section line A-A. The directional etching process can remove a portion of the offset material 116 (FIG. 4) from above the hardmask layer 106, the sidewall spacers 114, and the mandrel 110. A portion of the offset material 116 can remain along the sidewalls of the sidewall spacers 114, forming the offset spacers 118. Here, it should be noted that the offset spacers 118 depicted in FIG. 5 are for illustration purposes and generally can have a slightly different shape from those shown. For example, the offset spacers 118 can have rounded corners that can be naturally formed during the directional etching process as is known in the art. It should be noted that the directional etching technique used to form the offset spacers 118 may exposed the hardmask layer 106 in the planar device region 102 of the structure 100. It should also be noted that the etching technique used to form the offset spacers 118 from the offset material 116 may also recess the mandrel 110, such that a top surface of the mandrel 110 is below a top surface of the sidewall spacers 114. This may occur because the mandrel 110 may be made from the same material as the offset material 116.

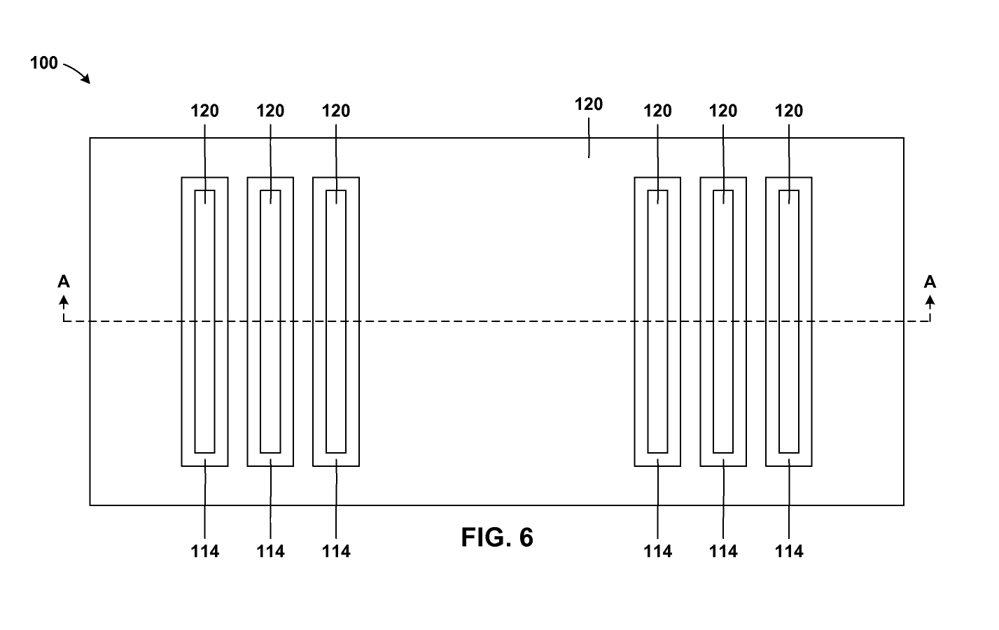

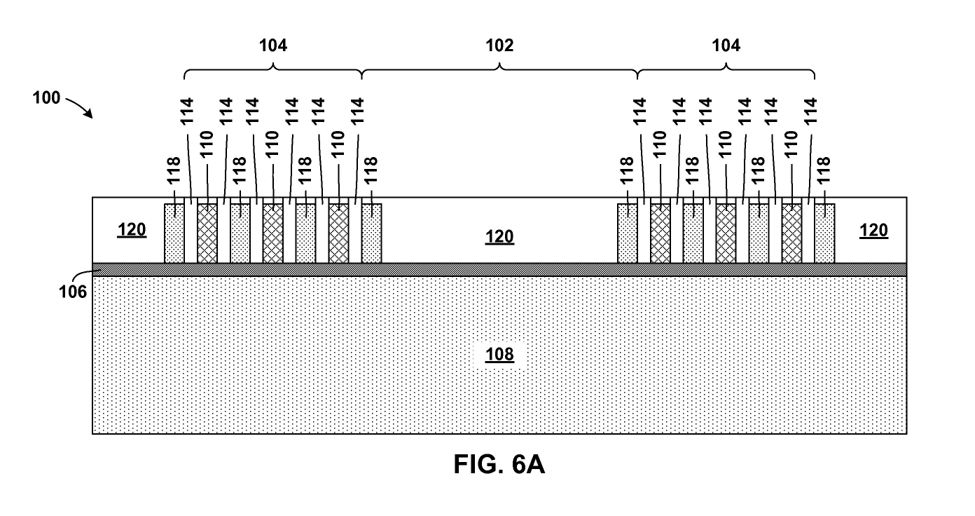

FIGS. 6 and 6A are a demonstrative illustration of the structure 100 during an intermediate step of a method of concurrently forming the planar device region and the finFET device region using a SIT finFET process flow according to one embodiment. More specifically, the method can include depositing a fill material 120 above the structure 100. FIG. 6 illustrates the structure 100 from a top view. FIG. 6A is a cross section view of FIG. 6 taken along section line A-A. The fill material 120 may be deposited on top of the structure 100 using any suitable deposition technique known in the art. The fill material 120 should serve to fill in the planar device region 102. In one embodiment, the fill material 120 may include any suitable oxide material know in the art. In one embodiment, the fill material 120 may include a high aspect ratio oxide deposited using a CVD deposition technique. The fill material 120 may have a thickness sufficient to cover the mandrel 110, the sidewall spacers 114, and the offset spacers 118. For example, the fill material 120 may have a thickness ranging from about 50 nm to about 1000 nm. In one embodiment, the fill material 120 may have a thickness ranging from about 200 nm to about 600 nm.

After being deposited on top of the structure 100, the fill material 120 may be planarized using a CMP technique. The CMP technique may remove some of the fill material 120 selective to, and exposing, the top surface of the sidewall spacers 114. In another embodiment, the fill material 120 may be polished selective to the mandrel 110, the sidewall spacers 114, or the offset spacers 118, which ever comes first. In one embodiment, the CMP technique may use a ceria based slurry to recess the fill material 120. It is known by a person of ordinary skill in the art that a CMP technique using a ceria based slurry stops great on silicon-nitride.

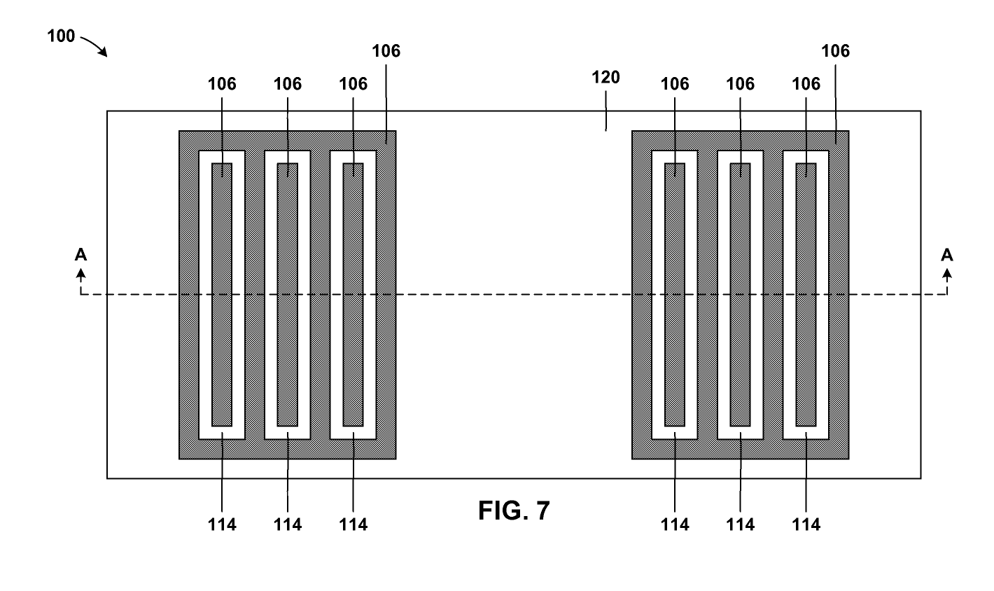

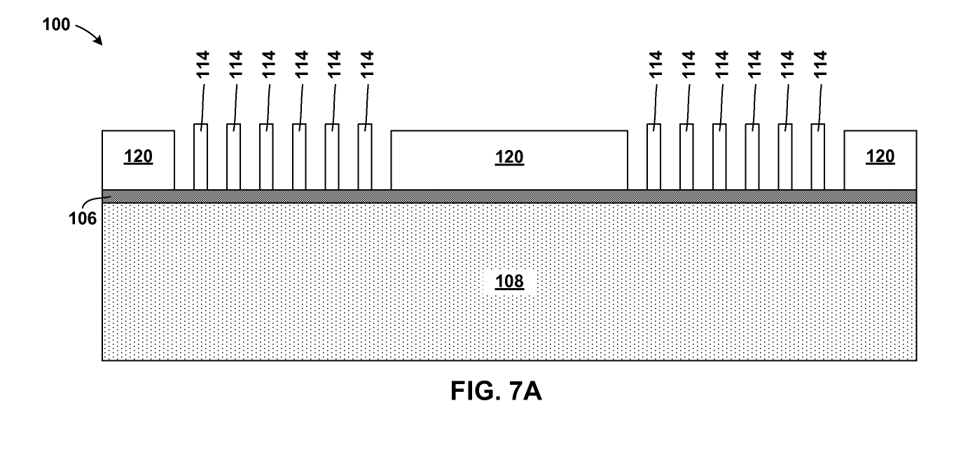

FIGS. 7 and 7A are a demonstrative illustration of the structure 100 during an intermediate step of a method of concurrently forming the planar device region and the finFET device region using a SIT finFET process flow according to one embodiment. More specifically, the mandrel 110 and the offset spacers 118 may be removed selective to the sidewall spacers 114 and the fill material 120. FIG. 7 illustrates the structure 100 from a top view. FIG. 7A is a cross section view of FIG. 7 taken along section line A-A. After deposition of the fill material 120, the mandrel 110 and the offset spacers 118 can be pulled out or removed. First, a non-selective breakthrough etch may be applied to exposed the mandrel 110 and the offset spacers 118. In one embodiment, the mandrel 110 and the offset spacers 118 are both silicon, and the sidewall spacers 114 and the fill material 120 are an oxide. In such cases, the silicon may be removed selective to the oxide. Furthermore, the mandrel 110 and the offset spacers 118 may be removed selective to the hardmask layer 106. In one embodiment, the mandrel 110 and the offset spacers 118 can be removed using a typical standard clean technique, including ammonium hydroxide and hydrogen peroxide, in which the sidewall spacers 114 won't be trimmed.

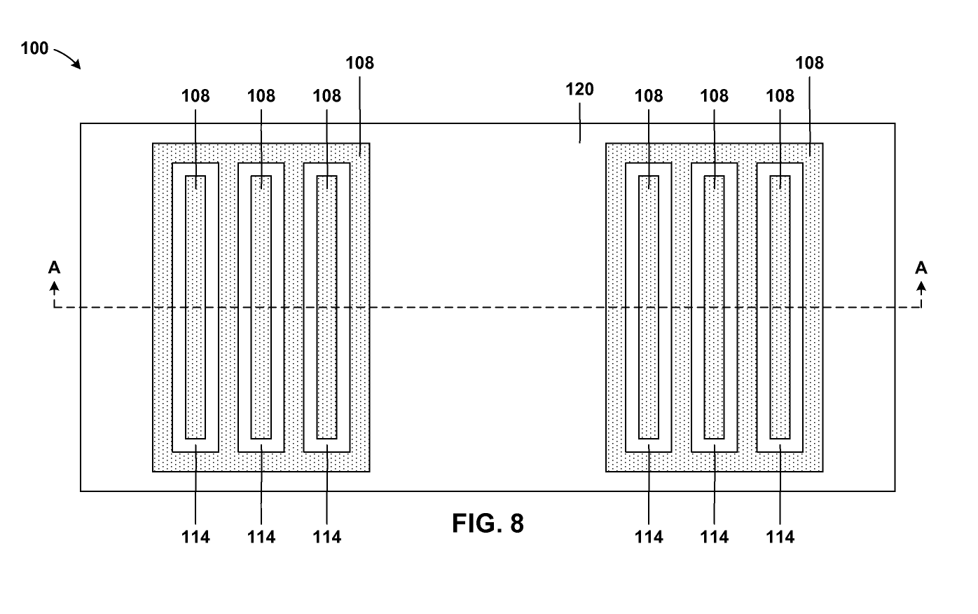

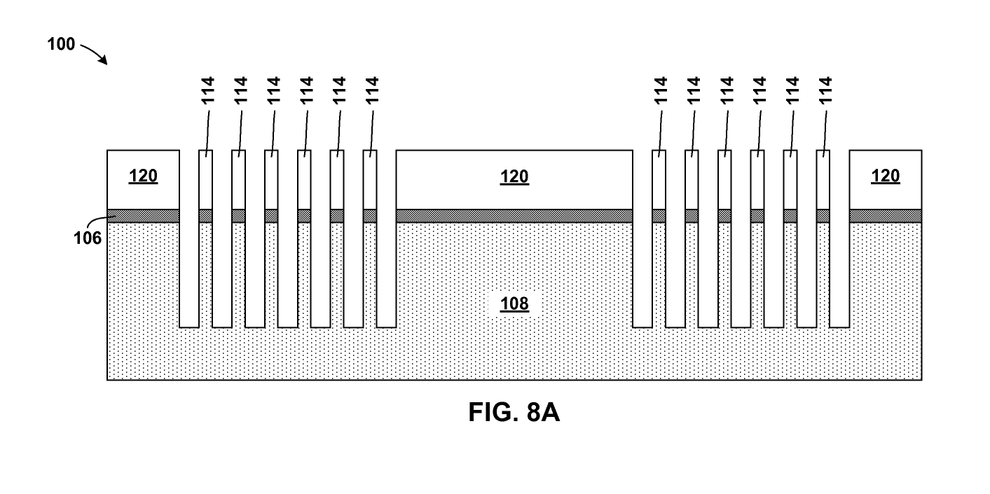

FIGS. 8 and 8A are a demonstrative illustration of the structure 100 during an intermediate step of a method of concurrently forming the planar device region and the finFET device region using a SIT finFET process flow according to one embodiment. More specifically, a fin pattern defined by the sidewall spacers 114 and the fill material 120 may be transferred into the substrate 108 using a multi-sequence etching technique. FIG. 8 illustrates the structure 100 from a top view. FIG. 8A is a cross section view of FIG. 8 taken along section line A-A. First, the hardmask layer 106 may be etched to expose the substrate 108. In doing so, the fill material 120 may simultaneously be lowered. A directional etching technique such as a reactive-ion-etching technique can be used to etch the hardmask layer 106. In one embodiment, where the hardmask layer 106 is an oxide, a reactive-ion-etching technique using a fluorocarbon based etchant with additional gases such as O2 or Ar may be used. In the present step, the sidewall spacers 114 can function as a mask, and can have high etch selectivity relative to the hardmask layer 106.

Next, the substrate 108 may then be etched to a desired depth. The desired depth can depend on the ultimate function of the structure 100. A directional etching technique such as a reactive-ion-etching technique can be used to etch the substrate 108. In one embodiment, the substrate 108 can be etched with a reactive-ion-etching technique using a chlorine or a bromine based etchant. In the present step, the hardmask layer 106 can function as a mask, and can have a high etch-selectivity relative to the substrate 108. Furthermore, the sidewall spacers 114, the fill material 120, and the hardmask layer 106 can be removed in subsequent steps using any suitable removal technique known in the art.

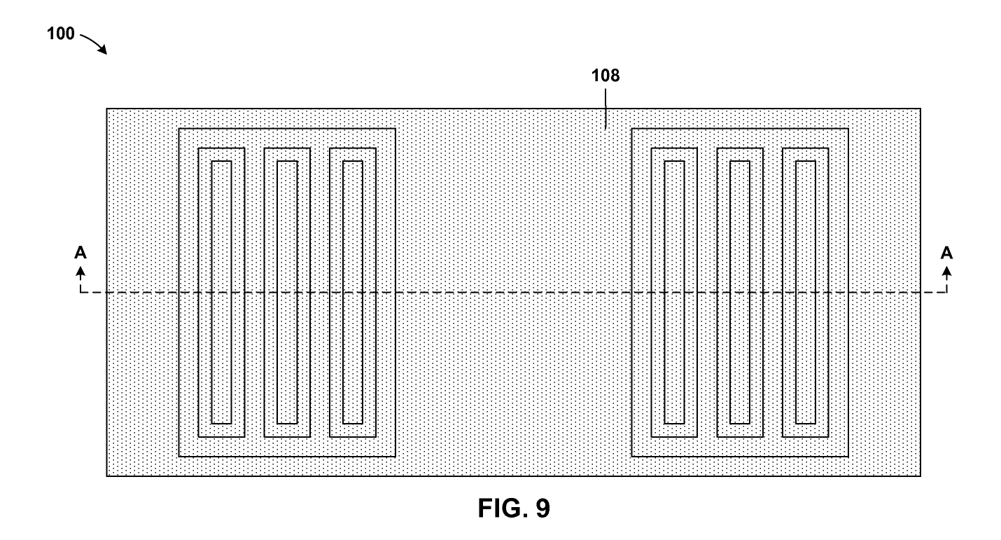

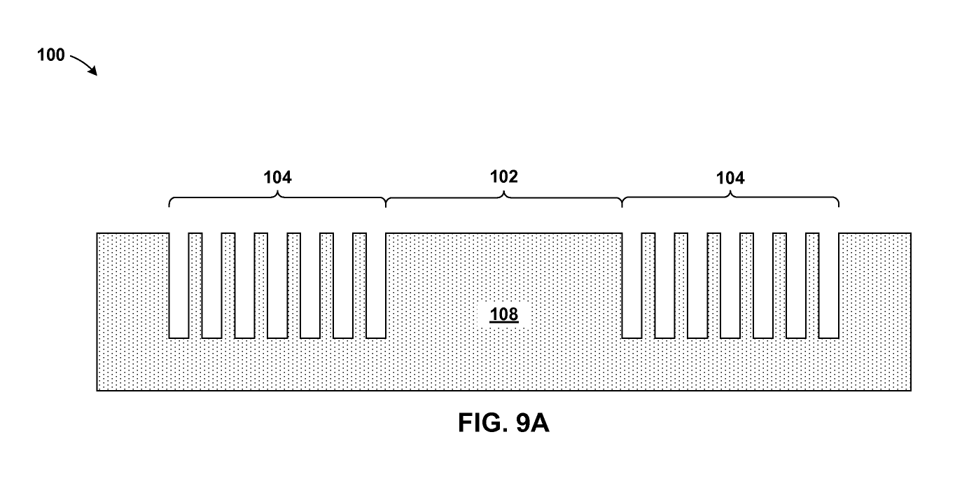

FIGS. 9 and 9A are is a demonstrative illustration of the final structure 100 of a method of concurrently forming the planar device region and the finFET device region using a SIT finFET process flow according to one embodiment. More specifically, the final structure 100 can include the planar device region 102 adjacent to the finFET region 104. FIG. 9 illustrates the structure 100 from a top view. FIG. 9A is a cross section view of FIG. 9 taken along section line A-A. A finFET semiconductor device may subsequently be formed in the finFET device region 104 and a planar semiconductor device may subsequently be formed in the planar device region 102.

The finFET device region 104 may include fins formed in the substrate 108 from which the finFET semiconductor device may subsequently be formed. The planar device region 102, also formed in the substrate 108, may have a planar area from which the planar semiconductor device may be formed. It should be noted that the top surface of the fins in the finFET device region 104 may be substantially flush with the top surface of the planar area in the planar device region 102. Additionally, a cut mask and an appropriate etching technique may be used to pattern active areas (not shown) within the finFET device region 104 and the planar device region 102. The cut mask may also be used to remove unwanted portions of the fins.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method comprising:
forming a plurality of mandrels, a plurality of sidewall spacers, and a plurality of offset spacers above a hardmask layer, the sidewall spacers being separated by the plurality of mandrels and the plurality of offset spacers in an alternating order, each of the plurality of sidewall spacers being in direct contact with a single offset spacer and a single mandrel, the plurality of mandrels being separated from the plurality of offset spacers by the plurality of sidewall spacers;
depositing a fill material above the plurality of mandrels, above the plurality of sidewall spacers, above the plurality of offset spacers, and above the hardmask layer; and
removing the plurality of mandrels and the plurality of offset spacers selective to the plurality of sidewall spacers, the fill material, and the hardmask layer.

2. The method of claim 1, wherein depositing the fill material above the plurality of mandrels, above the plurality of sidewall spacers, above the plurality of offset spacers, and above the hardmask layer comprises:
depositing a material having a high etch selectivity relative to the mandrel and the offset spacer.

3. The method of claim 1, wherein the plurality of mandrels and the plurality of offset spacers both comprise a material that which can be removed simultaneously using a similar removal technique selective to the plurality of sidewall spacers and the fill material.

4. The method of claim 1, further comprising:
transferring a fin pattern defined by the plurality of sidewall spacers and the fill material into a substrate below the hardmask layer.

5. The method of claim 4, further comprising:
removing the plurality of sidewall spacers from above the hardmask layer;
removing the fill material from above the hardmask layer; and
removing the hardmask layer from above the substrate.

6. The method of claim 1, further comprising:
patterning an active area using a cut mask.

7. The method of claim 4, wherein transferring the pattern defined by the plurality of sidewall spacers and the fill material into a substrate below the hardmask layer comprises:
transferring the fin pattern to the hardmask layer;
removing the plurality of sidewall spacers and the fill material; and
transferring the fin pattern from the hardmask layer to the substrate.

8. The method of claim 1, wherein forming the plurality of mandrels, the plurality of sidewall spacers, and the plurality of offset spacers above the hardmask layer comprises:
depositing an offset material above and between the plurality of sidewall spacers located along opposite sidewalls of the plurality of mandrels; and
removing a portion of the offset material to expose a top surface of the plurality of mandrels, and to expose a top surface of the plurality of sidewall spacers.

9. A method comprising:
forming a set of sidewall spacers above a hardmask layer along opposite sidewalls of a mandrel, the hardmask layer being on top of a substrate;
depositing an offset material above the mandrel and above the set of sidewall spacers, the offset material substantially filling a space between adjacent sidewall spacers;
removing a portion of the offset material to expose a top surface of the mandrel, a remaining portion of the offset material forming an offset spacer along a sidewall of the set of sidewall spacers;
depositing a fill material above the mandrel, above the set of sidewall spacers, and above the offset spacer;
removing the mandrel and the offset spacer selective to the set of sidewall spacers, the fill material, and the hardmask layer;
transferring a fin pattern defined by the set of sidewall spacers and the fill material oxide into the substrate; and
removing the set of sidewall spacers.

10. The method of claim 9, wherein forming the set of sidewall spacers above a hardmask layer along opposite sidewalls of a mandrel comprises:
creating the mandrel, lithographically, from a similar material as the offset material;
depositing a conformal layer of dielectric material above the hardmask layer and covering the mandrel; and
performing a directional etch of the conformal layer of dielectric material to form the set of sidewall spacers.

11. The method of claim 9, wherein depositing a fill material above the mandrel, above the set of sidewall spacers, and above the offset spacer comprises:
depositing a material having a high etch selectivity relative to the mandrel and the offset spacer.

12. The method of claim 9, wherein the mandrel and the offset spacer both comprise a material that which can be removed simultaneously using a similar removal technique selective to the fill material.

13. The method of claim 9, further comprising:
patterning an active area using a cut mask.

14. The method of claim 9, wherein transferring the fin pattern defined by the set of sidewall spacers and the fill material into a substrate below the hardmask layer comprises:
transferring the fin pattern into the hardmask layer;
removing the set of sidewall spacers and the fill material; and
transferring the fin pattern from the hardmask layer into the substrate.

15. The method of claim 9, further comprising removing a portion of the fill material to expose the top surface of the mandrel before removing the mandrel and the offset spacers.

16. A structure comprising:
a finFET device region comprising a plurality of fins made from a semiconductor material; and
a planar device region made from a similar semiconductor material as the finFET device region, a top surface of the plurality of fins in the finFET device region being substantially flush with a top surface of the planar device region.

17. The structure of claim 16, wherein the finFET device region comprises a finFET semiconductor device and the planar device region comprises a planar semiconductor device.

18. The structure of claim 16, wherein the semiconductor material comprises a bulk silicon substrate or a silicon-on-insulator substrate.

19. The structure of claim 16, wherein the finFET device region is adjacent to the planar device region.
